(19) United States
(12) Patent Application Publication
(10) Pub. No.: US 2024/0223099 A1
(43) Pub. Date: Jul. 4, 2024

(54) POWER DETECTING CIRCUIT BOARD, POWER DETECTING SYSTEM, AND IMMERSED LIQUID COOLING TANK

(71) Applicant: Fulian Precision Electronics (Tianjin) Co., LTD., Tianjin (CN)

(72) Inventors: DUO QIU, Tianjin (CN); LI-QUAN HE, Tianjin (CN); JEN-HUNG CHIANG, Taipei City (TW)

(21) Appl. No.: 18/204,813

(22) Filed: Jun. 1, 2023

(30) Foreign Application Priority Data
Dec. 30, 2022 (CN) 202211741906.X

(51) Int. Cl. H02M 7/00; G06F 1/28; H05K 1/14; H05K 7/20

(52) U.S. Cl. CPC H02M 7/003; G06F 1/28; H05K 1/141; H05K 7/20236; H05K 7/20763; G06F 13/4282

(57) ABSTRACT

A power detecting circuit board and, a power detecting system, and an immersed liquid cooling tank are provided, the power detecting system includes a plurality of power detecting circuit boards and a BMC, each power detecting circuit board is connected to at least one PSU, one of the power detecting circuit boards serves as a leader detecting circuit board, the rest of the power detecting circuit boards serve as follower detecting circuit boards; the leader detecting circuit board obtains running data of the corresponding PSU; each follower detecting circuit board obtains running data of the corresponding PSU; the leader detecting circuit board obtains the running data of the PSU corresponding to the follower detecting circuit boards, and summarize the running data of the PSU corresponding to the leader detecting circuit board and the running data of the PSU corresponding to the follower detecting circuit boards.

### CROSS-REFERENCE TO RELATED APPLICATIONS

This application claims priority to Chinese Patent Application No. 202211741906.X filed on Dec. 30, 2022, in China National Intellectual Property Administration, the contents of which are incorporated by reference herein.

### FIELD

The subject matter herein generally relates to power management technologies, and specially relates to a power detecting circuit board and, a power detecting system, and an immersed liquid cooling tank.

### BACKGROUND

With the development of the data center, the power density of a single cabinet in the data center is getting higher and higher, a traditional air cooling system can no longer meet the heat dissipation requirements of the data center, so it is gradually being replaced by a liquid cooling system. An immersion liquid cooling system is a type of liquid cooling system, and it is to directly immerse the load such as the server or heating element in the cooling liquid and package it in a liquid cooler tank, so that the flow circulation of the cooling liquid can take away the heat generated by the load. In addition, the immersion liquid cooling is a typical direct contact liquid cooling, which has higher heat dissipation efficiency and lower noise than other liquid cooling systems such as cold plate and spray liquid cooling and air cooling systems.

### BRIEF DESCRIPTION OF THE DRAWINGS

Implementations of the present disclosure will now be described, by way of example only, with reference to the attached figures.

FIG. 1 is a schematic diagram of an application scene of a liquid cooling tank in the related art.

FIG. 2 is a schematic diagram of an embodiment of an application scene of an immersed liquid cooling tank according to the present disclosure.

FIG. 3 is a schematic diagram of an embodiment of a circuit board for detecting power source according to the present disclosure.

FIG. 4 is a schematic diagram of an embodiment of a first connector of the circuit board for detecting power source according to the present disclosure.

FIG. 5 is a schematic diagram of an embodiment of a second connector of the circuit board for detecting power source according to the present disclosure.

FIG. 6 is a schematic diagram of an embodiment of a baseboard management controller (BMC) of the circuit board for detecting power source according to the present disclosure.

FIG. 7 is a flow chart of an embodiment of a communication method of the circuit board for detecting power source according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better show details and features of the present disclosure.

Several definitions that apply throughout this disclosure will now be presented.

The term “coupled” is defined as connected, whether directly or indirectly through intervening components, and is not necessarily limited to physical connections. The connection may be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but may have one or more deviations from a true cylinder. The term “comprising,” when utilized, means “including, but not necessarily limited to”; it specifically indicates open-ended inclusion or membership in the so-described combination, group, series, and the like.

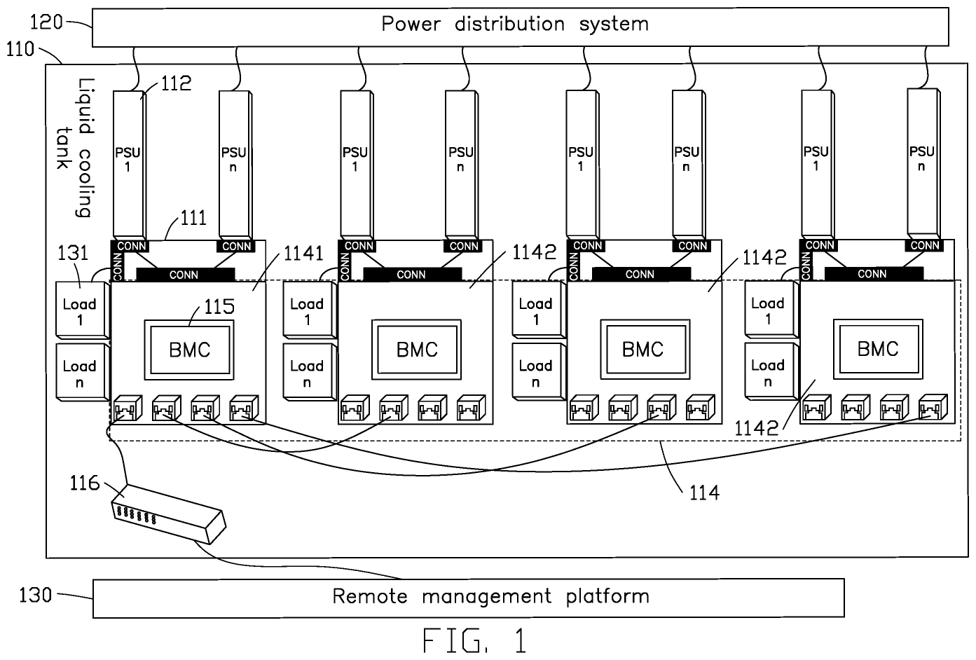

Immersed liquid cooling system uses central power supply system. FIG. 1 illustrates a schematic diagram of a liquid cooling tank 110 of an immersed liquid cooling system including a plurality of power shelfs 111. Each power shelf 111 may include a plurality of power supply units (PSU) 112. The PSUs 112 may convert alternating current of electric power supply of external power distribution system 120 into direct low-voltage current and provide same to loads 113 in the liquid cooling tank 110. Each power shelf 111 may be corresponding to a power management controller (PMC) 114. The PMC 114 may include a baseboard management controller (BMC) 115. The PMC 114 may further include a main detecting board 1141 and a slave detecting board 1142 communicating to the main detecting board 1141 through several ports. The main detecting board 1141 is configured to obtain running data of the PSUs 112 of the power shelf 111 corresponding to the slave detecting board 1142 from the slave detecting board 1142. The main detecting board 1141 is further connected to an interchanger 116 in the liquid cooling tank 110 through one of the ports. The main detecting board 1141 collects running data of the PSUs 112 of the power shelf 111 corresponding to the slave detecting board 1142 and running data of the PSUs 112 of the power shelf 111 corresponding to the main detecting board 1141, the main detecting board 1141 further transmits the collected running data of the PSUs 112 to an external remote management platform 300, so as to achieve out of band management (OOB). Each slave detecting board 1142 is configured to transmit the collected running data of the PSUs 112 of the corresponding power shelf 111 to the main detecting board 1141. However, the PMC 114 may include a plurality of ports, which occupies some space.

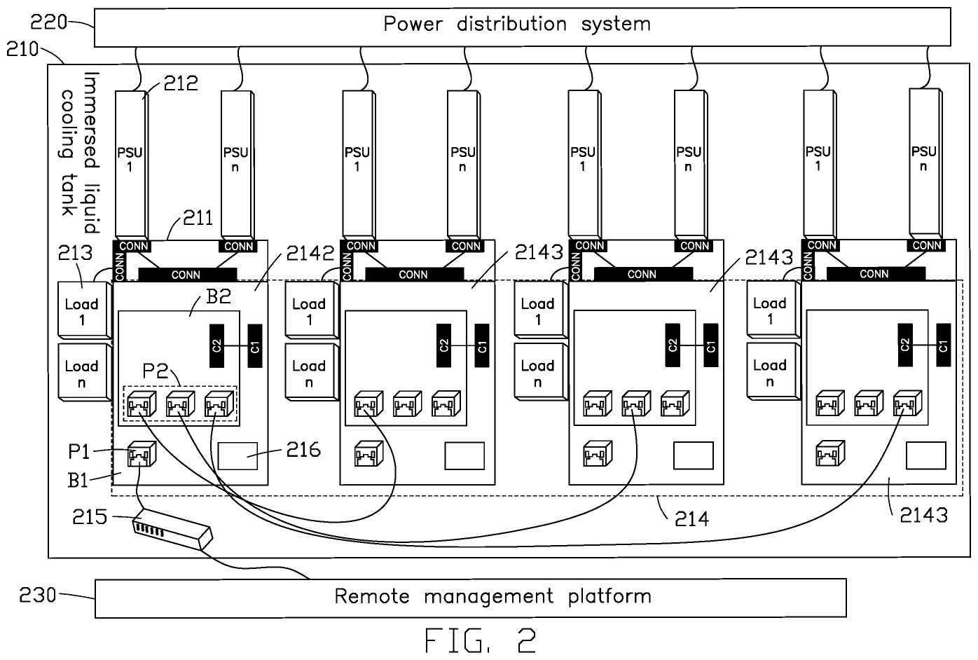

FIG. 2 illustrates a schematic diagram of at least one embodiment of an application scene of an immersed liquid cooling tank 210 according to the present disclosure. The immersed liquid cooling tank 210 is in communication with a power distribution system 220 and a remote management platform 130, 230. The immersed liquid cooling tank 210 includes a power shelf 211, a power supply unit (PSU) 212, a load 213, a power detecting system 214, and an interchanger 215. The power detecting system 214 includes a plurality of power detecting circuit boards 2141. It should be known that, the structure of the immersed liquid cooling tank 210 is not limited as shown in FIG. 2, the immersed liquid cooling tank 210 may include more or less components, may be engaged with other components, disassembled from other components, or rearranged the components.

In at least one embodiment, the immersed liquid cooling tank 210 may include a plurality of power shelfs 211. Each power shelf 211 may include a plurality of power supply units (PSU) 212. That is each power shelf 211 may receive the plurality of PSUs 212. The PSUs 212 are configured to convert the alternating current of the electric supply provided by the power distribution system 220 into low voltage direct current, to provide power supply for the load 213. In at least one embodiment, the load 213 can be a server or a heating element, etc. Each power shelf 211 may include a power detecting circuit board 2141. Each detecting circuit board 2141 is configured to detect running data of the PSUs 212 in the corresponding power shelf 211. In at least one embodiment, the PSUs 212 and the power detecting circuit board 2141 can be connected through a connecting module CONN. The power detecting circuit boards 2141 are further connected to the interchanger 215, to further communicate with the remote management platform 230 through the interchanger 215, and transmit the detected running data of the PSUs 212 to the remote management platform 230. In at least one embodiment, the power detecting circuit board 2141 can be a power management controller, a rank management controller (RMC), or a system management controller (SMC), etc., not limited by the present disclosure.

In detail, each power detecting circuit board 2141 includes a motherboard B1 and a daughter board B2. In at least one embodiment, both of the motherboard B1 and the daughter board B2 can be circuit boards, the motherboard B1 and the daughter board B2 can be overlapped, a size of the motherboard B1 is greater than a size of the daughter board B2. Thus, the overlapped arrangement of the motherboard B1 and the daughter board B2 may save a space of the power detecting circuit board 2141.

The motherboard B1 includes a first port P1, the daughter board B2 includes a second port P2. In at least one embodiment, the first port P1 can be a RJ45 port connected to a UART port or an Ethernet port of the motherboard B 1. The second port P2 can be a RJ45 port connected to a UART port or an Ethernet port of the daughter board B2.

The first port P1 is configured to provide the communication between the power detecting circuit boards 2141 and the remote management platform 230. In at least one embodiment, the first port P1 is configured to provide the communication between the power detecting circuit boards 2141 and the remote management platform 230 through the RJ45 port and the interchanger 215. The second port P2 is configured to provide the communication between the power detecting circuit boards 2141 and other power detecting circuit boards 2141. In at least one embodiment, the second port P2 is configured to provide the communication between the power detecting circuit boards 2141 and other power detecting circuit boards 2141 through cables.

Each of the power detecting circuit boards 2141 includes a leader detecting circuit board 2142 and at least one follower detecting circuit board 2143. The leader detecting circuit board 2142 may, use the second port P2, to communicate with the second port P2 of the follower detecting circuit board 2143. The leader detecting circuit board 2142 is configured to obtain the running data of the PSUs 212 of the corresponding power shelf 211, each follower detecting circuit board 2143 is configured to obtain the running data of the PSUs 212 of the corresponding power shelf 211. The leader detecting circuit board 2142 is further configured to obtain the running data of the PSUs 212 of the corresponding power shelf 211 corresponding to the follower detecting circuit board 2143 obtained by the follower detecting circuit board 2143. So the leader detecting circuit board 2142 summarizes the running data of the PSUs 212 of the power shelf 211 corresponding to the follower detecting circuit board 2143 and the running data of the PSUs 212 of the power shelf 211 corresponding to the leader detecting circuit board 2142. Each follower detecting circuit board 2143 is configured to transmit the running data of the PSUs 212 of the corresponding power shelf 211 to the leader detecting circuit board 2142. Thus, through the communication between the follower detecting circuit boards 2143 and the follower detecting circuit boards 2143, the follower detecting circuit boards 2143 may manage the follower detecting circuit boards 2143, the power distribution of the immersed liquid cooling tank 210 may be balanced.

In at least one embodiment, the first port P1 is configured to provide the leader detecting circuit board 2142 to transmit the summarized the running data of the PSUs 212 of the power shelf 211 corresponding to the follower detecting circuit board 2143 and the running data of the PSUs 212 of the power shelf 211 corresponding to the leader detecting circuit board 2142 to the remote management platform 230. Thus, an out-of-band management of the PSUs 212 in the immersed liquid cooling tank 210 may be achieved, through the management of the leader detecting circuit boards 2142 to the follower detecting circuit boards 2143, a complexity of the out-of-band management may be decreased.

In at least one embodiment, the second port P2 is configured to provide the communication between the leader detecting circuit board 2142 and the follower detecting circuit board 2143. As shown in FIG. 2, one leader detecting circuit board 2142 and three follower detecting circuit boards 2143 are set for example. It should be known that, the quantity of each of the leader detecting circuit board 2142 and the follower detecting circuit board 2143 are not limited, for instance, the quantity of the leader detecting circuit board 2142 can be two or three, the quantity of the follower detecting circuit board 2143 communicating with the leader detecting circuit boards 2142 can be same or different, not limited by the present disclosure. Since the quantity of each of the leader detecting circuit board 2142 and the follower detecting circuit board 2143 are different, the quantity of the second port P2 can be different accordingly. As shown in FIG. 2, the leader detecting circuit board 2142 can be connected to three follower detecting circuit boards 2143 through three second ports P2 and cables, each of the three follower detecting circuit boards 2143 is connected to the leader detecting circuit board 2142 through one second port P2 and cable.

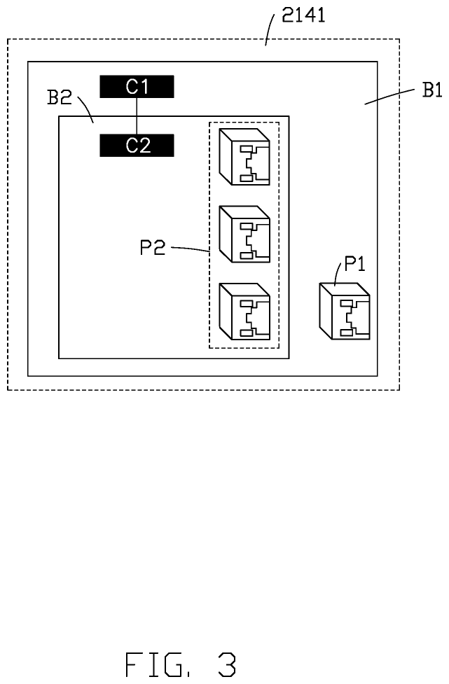

In detail, referring to FIG. 3, in each power detecting circuit board 2141, the motherboard B1 includes a first connector C1, the daughter board B2 includes a second connector C2, the motherboard B1 and the daughter board B2 can be connected through connecting the first connector C1 and the second connector C2. In at least one embodiment, the first connector C1 and the second connector C2 can be a same type of connector, such as 2×15pin connector.

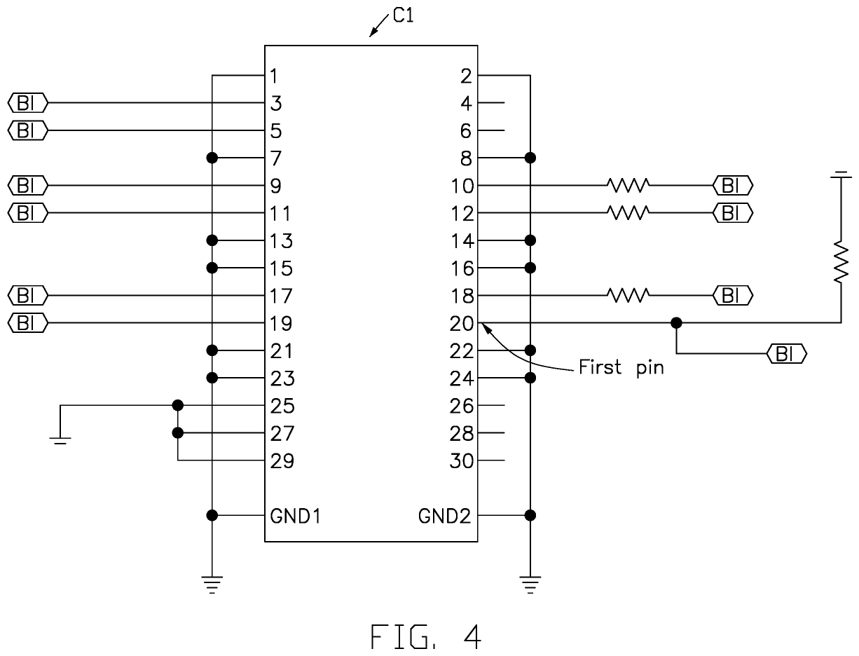

The first connector C1 includes a first pin, the first pin is connected to a power source through a first resistor R1, to maintain a level of the first pin in a high-level status. Referring to FIG. 4, the first connector C1 being 2×15pin connector is set for example for introducing the motherboard B1. The first pin of the first connector C1 can be PIN20 of the 2×15pin connector. In at least one embodiment, the first resistor R1 can be a pull-up resistor having a value of resistance of 4.7 kilo-ohm (kΩ).

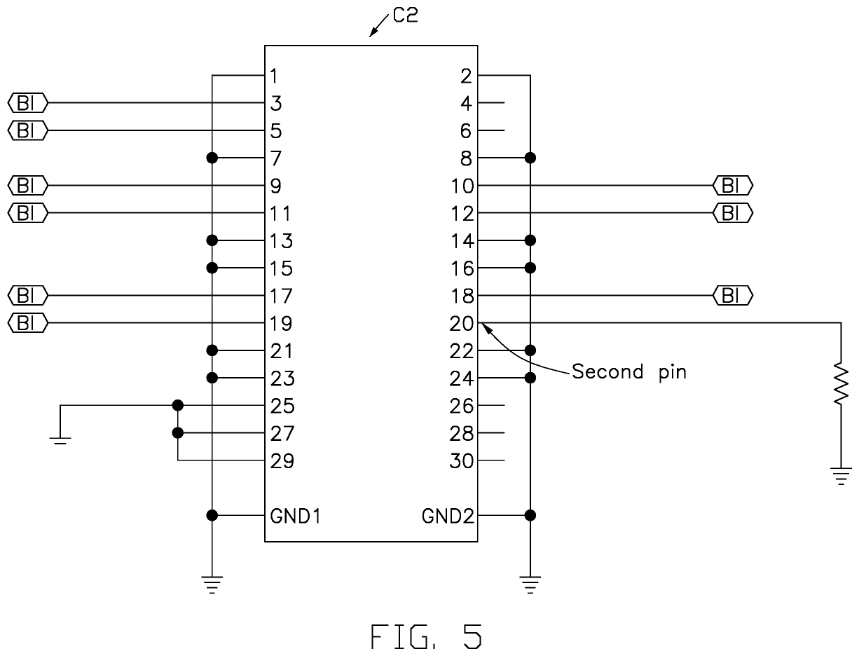

The second connector C2 includes a second pin, the second pin is grounded through a second resistor R2, to maintain a level of the second pin in a low-level status. Referring to FIG. 5, the second connector C2 being 2×15pin connector is set for example for introducing the daughter board B2. The second pin of the second connector C2 can be PIN20 of the 2×15pin connector. In at least one embodiment, the second resistor R2 can be a pull-down resistor having a value of resistance of 100 ohm (Ω).

In detail, between the first connector C1 and the second connector C2, the first pin and the second pin can be connected or disconnected, other pins of the first connector C1 and other pins of the second connector C2 can be correspondingly connected one-to-one.

In at least one embodiment, in the leader detecting circuit board 2142, the first pin of the first connector C1 and the second pin of the second connector C2 are suspended and not connected, other pins of the first connector C1 and other pins of the second connector C2 can be correspondingly connected one-to-one. In at least one embodiment, other pins of the first connector C1 can be also named as third pins, other pins of the second connector C2 can be also named as fourth pins. In at least one embodiment, in the follower detecting circuit board 2143, all the pins of the first connector C1 and all the pins of the second connector C2 are correspondingly connected one-to-one. It should be known that, when the first pin of the first connector C1 and the second pin of the second connector C2 are connected, the level of the first pin of the first connector C1 may be pulled down by the level of the second pin of the second connector C2, so the first pin of the first connector C1 may be in the low-level status.

The motherboard B1 of each power detecting circuit board 2141 includes a baseboard management controller (BMC) 216. The BMC 216 is configured to determine the corresponding power detecting circuit board 2141 being the leader detecting circuit board 2142 or the follower detecting circuit board 2143, and control the running of the power detecting circuit board 2141 according to the determined result, such as the detecting function and the data transmitting function of the power detecting circuit board 2141. In at least one embodiment, the BMC 216 can be a AST26XX serial chip. Comparing to other chips, the AST26XX serial chip has an advantage of having more Universal Asynchronous Receiver and Transmitter (UART) ports. It should be known that, the BMC 216 can be a AST25XX serial chip or a AST24XX serial chip, not limited by the present disclosure. Each UART port of the BMC 216 can be connected to the corresponding motherboard B1 through the connecting module CONN.

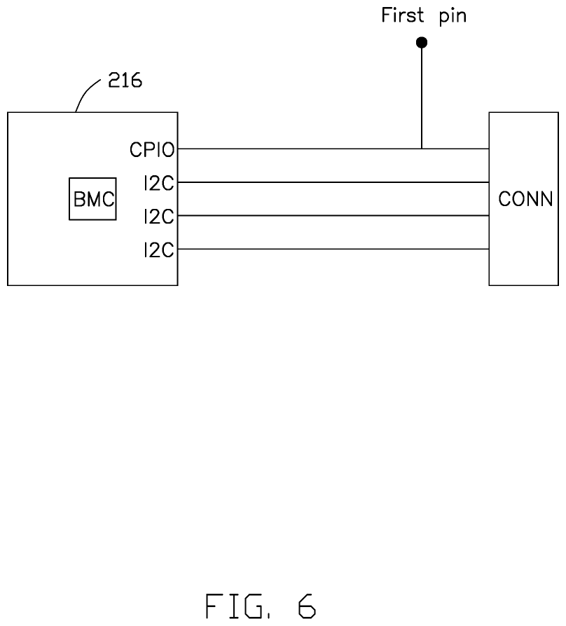

Referring to FIG. 6, in each of the power detecting circuit boards 2141, a General-purpose input/output (GPIO) port and a I2C port of the BMC 216 are connected to the corresponding motherboard B1 through the connecting module CONN. The GPIO port is connected to the first pin of the first connector C1 of the motherboard B1, so as to detect whether the power detecting circuit boards 2141 is the leader detecting circuit board 2142 according to the level status of the first pin of the first connector C1. In detail, when the level status of the first pin of the first connector C1 connected to the GPIO port is a high-level status, the BMC 216 determines the power detecting circuit board 2141 is the leader detecting circuit board 2142. When the level status of the first pin of the first connector C1 connected to the GPIO port is a low-level status, the BMC 216 determines the power detecting circuit board 2141 is the follower detecting circuit board 2143.

Furthermore, when the BMC 216 determines the power detecting circuit board 2141 is the leader detecting circuit board 2142, the BMC 216, by configuring the I2C port, controls the leader detecting circuit board 2142 to detect the running data of the PSUs 212 of the corresponding power shelf 211, and polls the running data of the PSUs 212 of the power shelf 211 corresponding to each follower detecting circuit board 2143. The BMC 216 further controls the leader detecting circuit board 2142 to summarize the running data of the PSUs 212 of the power shelf 211 corresponding to the follower detecting circuit board 2143 and the running data of the PSUs 212 of the power shelf 211 corresponding to the leader detecting circuit board 2142, and transmit the summarized running data of the PSUs 212 of the power shelf 211 corresponding to the follower detecting circuit board 2143 and the running data of the PSUs 212 of the power shelf 211 corresponding to the leader detecting circuit board 2142 to the remote management platform 230, to perform out-of-band management to the PSUs 212 in the immersed liquid cooling tank 210.

When the BMC 216 determines the power detecting circuit board 2141 is the follower detecting circuit board 2143, the BMC 216, by configuring the I2C port, controls the follower detecting circuit boards 2143 to detect the running data of the PSUs 212 of the corresponding power shelf 211, and transmit the detected running data of the PSUs 212 of the power shelf 211 corresponding to the follower detecting circuit board 2143 to the leader detecting circuit board 2142.

Thus, by the BMC 216 determining the level status of the PIN20 of the first connector C1 to determine the leader detecting circuit boards 2142 and the follower detecting circuit boards 2143, so as to improve an efficiency and precision of the determination of the leader detecting circuit boards 2142 and the follower detecting circuit boards 2143.

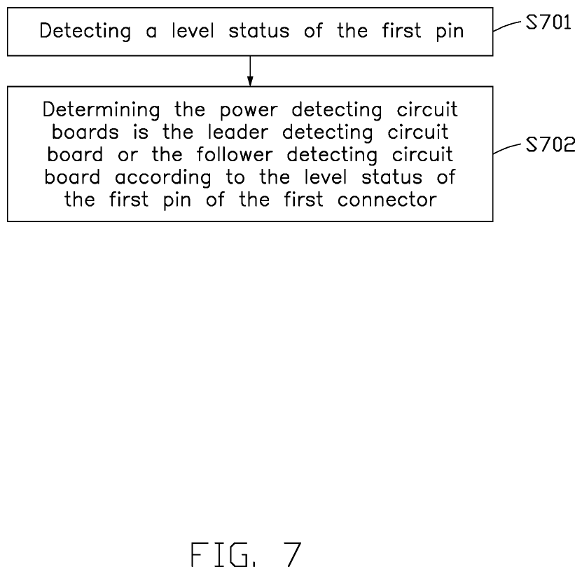

FIG. 7 illustrates a flow chart of at least one embodiment of a communication method of the circuit board for detecting power source, which may be applied in the power detecting circuit board 2141 in the immersed liquid cooling tank 210. The communication method may include:

At block S701, detecting a level status of the first pin.

In detail, the GPIO port of the BMC 216 is connected to the first pin of the first connector C1 of the motherboard B1, so as to detect whether the power detecting circuit boards 2141 is the leader detecting circuit board 2142 according to the level status of the first pin of the first connector C1.

At block S702, determining the power detecting circuit boards 2141 is the leader detecting circuit board 2142 or the follower detecting circuit board 2143 according to the level status of the first pin of the first connector C1.

In at least one embodiment, when the level status of the first pin of the first connector C1 connected to the GPIO port is a high-level status, the BMC 216 determines the power detecting circuit boards 2141 is the leader detecting circuit board 2142.

In at least one embodiment, when the BMC 216 detects the level status of the first pin of the first connector C1 connected to the GPIO port is a high-level status, the BMC 216 determines the power detecting circuit boards 2141 is the leader detecting circuit board 2142, and by configuring the I2C port, controls the leader detecting circuit board 2142 to detect the running data of the PSUs 212 of the corresponding power shelf 211, and polls the running data of the PSUs 212 of the power shelf 211 corresponding to each follower detecting circuit board 2143. The BMC 216 further controls the leader detecting circuit board 2142 to summarize the running data of the PSUs 212 of the power shelf 211 corresponding to the follower detecting circuit board 2143 and the running data of the PSUs 212 of the power shelf 211 corresponding to the leader detecting circuit board 2142, and transmit the summarized running data of the PSUs 212 of the power shelf 211 corresponding to the follower detecting circuit board 2143 and the running data of the PSUs 212 of the power shelf 211 corresponding to the leader detecting circuit board 2142 to the remote management platform 230, to perform out-of-band management to the PSUs 212 in the immersed liquid cooling tank 210.

In at least one embodiment, when the level status of the first pin of the first connector C1 connected to the GPIO port is a low-level status, the BMC 216 determines the power detecting circuit boards 2141 is the follower detecting circuit board 2143.

In at least one embodiment, when the when the BMC 216 detects the level status of the first pin of the first connector C1 connected to the GPIO port is a low-level status, the BMC 216 determines the power detecting circuit boards 2141 is the follower detecting circuit boards 2143, the BMC 216, by configuring the I2C port, controls the follower detecting circuit boards 2143 to detect the running data of the PSUs 212 of the corresponding power shelf 211, and transmit the detected running data of the PSUs 212 of the power shelf 211 corresponding to the follower detecting circuit boards 2143 to the leader detecting circuit boards 2142.

The present disclosure provides the power detecting circuit boards 2141, the power detecting system 214, the immersed liquid cooling tank 210, and the control method. The power detecting circuit board 2141 includes the motherboard B1 and the daughter board B2, the motherboard B1 includes the first connector C1, the first connector C1 includes the first pin, the daughter board B2 includes the second connector C2, the first connector C1 and the second connector C2 are connected, so the BMC 216 of the motherboard B1 determines the power detecting circuit board 2141 is the leader detecting circuit board 2142 or the follower detecting circuit board 2143. Thus, the power detecting circuit boards 2141 is saving space in the immersed liquid cooling tank 210, and improving an efficiency and precision of the determination of the leader detecting circuit boards 2142 and the follower detecting circuit boards 2143.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A power detecting circuit board electrically connected to at least one power supply unit (PSU), the at least one PSU configured to convert alternating current of an electric supply provided by a power distribution system into direct current, to provide power supply for at least one corresponding server, the power detecting circuit board configured to detect running data of the at least one PSU; the power detecting circuit board comprising:
a motherboard comprising a first connector; and
a daughter board overlapped with the motherboard, the daughter board comprising a second connector, the second connector electrically connected to the first connector.

2. The power detecting circuit board of claim 1, wherein the first connector comprises a first pin, the second connector comprises a second pin; the first pin is connected to a power source through a first resistor, the second pin is grounded through a second resistor, the first pin and the second pin are switchable to be connected or disconnected.

3. The power detecting circuit board of claim 2, wherein the first connector further comprises a plurality of third pins; the second connector further comprises a plurality of fourth pins, the plurality of third pins of the first connector and the plurality of fourth pins of the second connector are correspondingly connected one-to-one.

4. The power detecting circuit board of claim 2, wherein the motherboard further comprises a first port, the power detecting circuit board is connected to a remote management platform through the first port;
the daughter board further comprises a second port, the power detecting circuit board is connected to other power detecting circuit boards through the second port.

5. The power detecting circuit board of claim 4, wherein the motherboard further comprises a baseboard management controller (BMC), the BMC comprises a General-purpose input/output (GPIO) port, the GPIO port is connected to the first pin of the first connector and configured to detect a level status of the first pin.

6. A power detecting system applied in a liquid cooling tank, the power detecting system comprising:
a plurality of power detecting circuit boards connected to each other, each of the plurality of power detecting circuit boards electrically connected to at least one power supply unit (PSU), the at least one PSU configured to convert alternating current of an electric supply provided by a power distribution system into direct current, to provide power supply for at least one corresponding server;
each of the plurality of power detecting circuit boards comprising:
a motherboard comprising a first connector; and
a daughter board overlapped with the motherboard, the daughter board comprising a second connector, the second connector electrically connected to the first connector;
one of the plurality of power detecting circuit boards serving as a leader detecting circuit board in the power detecting system, rest of the plurality of power detecting circuit boards serving as follower detecting circuit boards in the power detecting system;
wherein the leader detecting circuit board is configured to obtain running data of the at least one PSU corresponding to the leader detecting circuit board; and
each of the follower detecting circuit boards is configured to obtain running data of the at least one PSU corresponding to each of the follower detecting circuit boards;
wherein the leader detecting circuit board is further configured to obtain the running data of the at least one PSU corresponding to the follower detecting circuit boards, and summarize the running data of the at least one PSU corresponding to the leader detecting circuit board and the running data of the at least one PSU corresponding to the follower detecting circuit boards.

7. The power detecting system of claim 6, wherein the leader detecting circuit board is further configured to transmit the summarized of the running data of the at least one PSU corresponding to the leader detecting circuit board and the running data of the at least one PSU corresponding to the follower detecting circuit boards to a remote management platform.

8. The power detecting system of claim 6, wherein the first connector comprises a first pin, the second connector comprises a second pin, the first pin is connected to a power source through a first resistor, the second pin is grounded through a second resistor, the first pin and the second pin are switchable to be connected or disconnected.

9. The power detecting system of claim 8, wherein:
in the leader detecting circuit board, the first pin and the second pin are disconnected;
in each of the follower detecting circuit boards, the first pin and the second pin are connected.

10. The power detecting system of claim 7, wherein each of the motherboards further comprises a first port, the plurality of power detecting circuit boards is connected to the remote management platform through the first port;
each of the daughter boards further comprises a second port, the leader detecting circuit board is connected to the follower detecting circuit boards through the second ports of each of the leader detecting circuit board and the follower detecting circuit boards.

11. The power detecting system of claim 8, wherein each of the motherboards further comprises a baseboard management controller (BMC), the BMC comprises a General-purpose input/output (GPIO) port, the GPIO port is connected to the first pin of the first connector and configured to detect a level status of the first pin, to determine each of the plurality of power detecting circuit boards comprising the BMC is the leader detecting circuit board or one of the follower detecting circuit board, and the BMC controls a running of each of the plurality of power detecting circuit board according to a determined result.

12. The power detecting system of claim 11, wherein when the level status of the first pin of the first connector connected to the GPIO port is a high-level status, the BMC determines the power detecting circuit board comprising the BMC is the leader detecting circuit board;
when the level status of the first pin of the first connector connected to the GPIO port is a low-level status, the BMC determines the power detecting circuit board comprising the BMC is one of the follower detecting circuit board.

13. The power detecting system of claim 12, wherein when the BMC determines the power detecting circuit board comprising the BMC is the leader detecting circuit board, the BMC controls the leader detecting circuit board to detect the running data of the at least one PSU corresponding to the leader detecting circuit board, and polls the running data of the at least one PSU corresponding to the follower detecting circuit boards, to summarize the running data of the at least one PSU corresponding to the leader detecting circuit board and the running data of the at least one PSU corresponding to the follower detecting circuit boards;
when the BMC determines the power detecting circuit board comprising the BMC is the follower detecting circuit board, the BMC controls the follower detecting circuit board to detect the running data of the at least one PSU corresponding to the follower detecting circuit board, and to transmit the detected running data of the at least one PSU to the leader detecting circuit board.

14. An immersed liquid cooling tank communicating with a power distribution system and a remote management platform, the immersed liquid cooling tank comprising:
a plurality of power supply units (PSUs) configured to convert alternating current of an electric supply provided by a power distribution system into direct current, to provide power supply for at least one corresponding server; and
a power detecting system comprising:
a plurality of power detecting circuit boards connected to each other, each of the plurality of power detecting circuit boards electrically connected to at least one of the plurality of PSUs;
each of the plurality of power detecting circuit boards comprising:
a motherboard comprising a first connector; and
a daughter board overlapped with the motherboard, the daughter board comprising a second connector, the second connector electrically connected to the first connector;
one of the plurality of power detecting circuit boards serving as a leader detecting circuit board in the power detecting system, rest of the plurality of power detecting circuit boards serving as follower detecting circuit boards in the power detecting system;
the leader detecting circuit board is configured to obtain running data of the at least one PSU corresponding to the leader detecting circuit board;
each of the follower detecting circuit boards is configured to obtain running data of the at least one PSU corresponding to each of the follower detecting circuit boards; and
the leader detecting circuit board is further configured to obtain the running data of the at least one PSU corresponding to the follower detecting circuit boards, and summarize the running data of the at least one PSU corresponding to the leader detecting circuit board and the running data of the at least one PSU corresponding to the follower detecting circuit boards.

15. The immersed liquid cooling tank of claim 14, wherein the leader detecting circuit board is further configured to transmit the summarized of the running data of the at least one PSU corresponding to the leader detecting circuit board and the running data of the at least one PSU corresponding to the follower detecting circuit boards to a remote management platform.

16. The immersed liquid cooling tank of claim 14, wherein the first connector comprises a first pin, the second connector comprises a second pin, the first pin is connected to a power source through a first resistor, the second pin is grounded through a second resistor, the first pin and the second pin are switchable to be connected or disconnected; wherein
in the leader detecting circuit board, the first pin and the second pin are disconnected;
in each of the follower detecting circuit boards, the first pin and the second pin are connected.

17. The immersed liquid cooling tank of claim 15, wherein the motherboard further comprises a first port, the power detecting circuit board is connected to the remote management platform through the first port;
the daughter board further comprises a second port, the leader detecting circuit board is connected to the follower detecting circuit boards through the second ports of each of the leader detecting circuit board and the follower detecting circuit boards.

18. The immersed liquid cooling tank of claim 16, wherein the motherboard further comprises a baseboard management controller (BMC), the BMC comprises a General-purpose input/output (GPIO) port, the GPIO port is connected to the first pin of the first connector and configured to detect a level status of the first pin, to determine the power detecting circuit board comprising the BMC being the leader detecting circuit board or the follower detecting circuit board, and control a running of the power detecting circuit board according to the determined result.

19. The immersed liquid cooling tank of claim 18, wherein when the level status of the first pin of the first connector connected to the GPIO port is a high-level status, the BMC determines the power detecting circuit board comprising the BMC is the leader detecting circuit board;
when the level status of the first pin of the first connector connected to the GPIO port is a low-level status, the BMC determines the power detecting circuit board comprising the BMC is the follower detecting circuit board.

20. The immersed liquid cooling tank of claim 19, wherein when the BMC determines the power detecting circuit board comprising the BMC is the leader detecting circuit board, the BMC controls the leader detecting circuit board to detect the running data of the at least one PSU corresponding to the leader detecting circuit board, and polls the running data of the at least one PSU corresponding to the follower detecting circuit boards, and to summarize the running data of the at least one PSU corresponding to the leader detecting circuit board and the running data of the at least one PSU corresponding to the follower detecting circuit boards;
when the BMC determines the power detecting circuit board comprising the BMC is the follower detecting circuit board, the BMC controls the follower detecting circuit board to detect the running data of the at least one PSU corresponding to the follower detecting circuit board, and to transmit the detected running data of the at least one PSU to the leader detecting circuit board.
